(19) United States
(12) Patent Application Publication
(10) Pub. No.: US 2013/0286319 A1
(43) Pub. Date: Oct. 31, 2013

(54) LCD Device and Backlight Module

(71) Applicants: Yicheng Kuo, Shenzhen (CN); Shihhsiang Chen, Shenzhen (CN); Gang Yu, Shenzhen (CN); Gege Zhou, Shenzhen (CN); Jiaqiang Wang, Shenzhen (CN)

(72) Inventors: Yicheng Kuo, Shenzhen (CN); Shihhsiang Chen, Shenzhen (CN); Gang Yu, Shenzhen (CN); Gege Zhou, Shenzhen (CN); Jiaqiang Wang, Shenzhen (CN)

(21) Appl. No.: 13/515,274

(22) PCT Filed: May 9, 2012
(86) PCT No.: PCT/CN12/75231

§ 371 Date: Jun. 11, 2012

(30) Foreign Application Priority Data
Apr. 28, 2012 (CN) 201210132867.3

(51) Int. Cl. G02F 1/1333; H05K 5/02

(52) U.S. Cl. 349/58; 361/679.01

(57) ABSTRACT

The invention relates to the field of LCDs, and more particularly to an LCD device and a backlight module. The LCD device includes a middle frame, a backplane, and an LCD panel; the LCD panel is arranged on a support surface of the middle frame; the middle frame comprises a plurality of member units, and a distance is reserved between two adjacent member units. The LCD device further includes a support member(s) used for assistantly supporting the LCD panel. The support member is provided with a hook, and the support member is hung on the side wall of the backplane by the hook. The support member(s) is positioned between two adjacent member units, and the support surface of the support member is flush with the support surface of the middle frame. The support member(s) of the LCD panel is additionally arranged on the LCD device of the invention, and the support member(s) is arranged between two member units when the distance between two adjacent member units is long, so as to enable the support force obtained by the LCD panel is more uniform, and prevent excessive local stress.

### TECHNICAL FIELD

The invention relates to the field of liquid crystal displays (LCDs), and more particularly to an LCD device and a backlight module.

### BACKGROUND

A conventional LCD device generally includes a front frame, an LCD panel, a middle frame, a backlight module, a back cover and the like. The backlight module includes an optical film, a light guide panel (LGP), a lightbar and the like. The front frame, the middle frame and the back cover respectively have different functions; the front frame is mainly used for fixing the LCD panel and preventing the LCD panel from escaping, the middle frame is mainly used for bearing the LCD panel and shielding partial backlight module from light leakage, and the back cover is mainly used for bearing the optical film, the LGP, the lightbar and the like and ensuring the planeness of the backlight module.

To save cost, a part of the LCD devices employ a segmented middle frame. The middle frame includes a plurality of member units; the member units are respectively fixed on the backplane or the front frame, and a distance is reserved between every two member units. The same member units are applied to the LCD devices of various sizes; thus, the material is reduced to be used, and the development cost and cycle of LCD devices are reduced.

Because the middle frame is of a segmented structure, the support surface of the middle frame is also discontinuous; thus, the support force applied to the LCD panel is nonuniform. When the distance between two adjacent member units of the LCD device is long, the planeness of the LCD panel is affected to some extent, and excessive local stress is easily generated on the LCD panel. The LCD panel includes thin glass substrate(s) which is hard and fragile, and the glass substrate is easily damaged because of stress concentration, resulting in adverse effect on the quality of the whole LCD device.

### SUMMARY

In view of the above-described technical problems, the aim of the invention is to provide an LCD device and a backlight module with a segmented middle frame and low cost. The LCD device and the backlight module can ensure that the LCD panel is supported by an uniform force, and avoid excessive local stress.

A first technical scheme of the invention is that: an LCD device comprises a middle frame, a backplane, and an LCD panel; the LCD panel is arranged on a support surface of the middle frame; the middle frame comprises a plurality of member units, and a distance is reserved between two adjacent member units. The LCD device further comprises a support member(s) used for assistantly supporting the LCD panel. The support member is provided with a hook, and the support member is hung on one side wall of the backplane by the hook. The support member(s) is positioned between two adjacent member units, and the support surface of the support member is flush with the support surface of the middle frame. The support member is formed by bending a plate. The width of the hook of the support member is equal to the length of the support member, and the width of the support surface is less than or equal to that of the support surface of the middle frame. The side wall of the backplane is further provided with a positioning structure used for preventing the support member from sliding on the side wallr. The positioning structure comprises a through hole arranged in the support member, and a lug boss arranged on the upper end surface of the side wall of the backplane; the through hole is sheathed on the lug boss. The member units are frame corner members, and are distributed on the four corners of the backplane; or the member units are frame edge members, and are distributed on the four edges of the backplane. The number of the support members arranged between part of adjacent member units is multiple.

A second technical scheme of the invention is that: an LCD device comprises a middle frame, a backplane, and an LCD panel; the LCD panel is arranged on a support surface of the middle frame; the middle frame comprises a plurality of member units, and a distance is reserved between two adjacent member units. The LCD device further comprises a support member(s) for assistantly supporting the LCD panel. The support member is provided with a hook, and the support member is hung on one side wall of the backplane by the hook. The support member is positioned between two adjacent member units, and the support surface of the support member is flush with the support surface of the middle frame.

Preferably, the support member is formed by bending a plate. The width of the hook of the support member is equal to the length of the support member, thereby avoiding the inclination of the support member, to enable the support surface of the support member to be fully attached to the surface of the LCD panel.

Preferably, the width of the support surface of the support member is less than or equal to that of the support surface of the middle frame, to avoid blocking out the light emitted by the backlight module.

Preferably, the side wall of the backplane is further provided with a positioning structure used for preventing the support member from sliding on the side wall. The positioning structure enables the support member to have a fixed position, and then enables the LCD panel to obtain reasonable support force in an appropriate position and not to be affected by the factors such as position error when being manually placed.

Preferably, the positioning structure comprises a through hole arranged in the support member, and a lug boss arranged on the upper end surface of the side wall of the backplane; the through hole is sheathed on the lug boss.

Preferably, the positioning structure comprises a notch arranged in the side wall of the backplane; the width of the notch is longer than or equal to the length of the support member, and the support member is limited in the notch.

Preferably, the member units are frame corner members, and are distributed on the four corners of the backplane; or the member units are frame edge members, and are distributed on the four edges of the backplane.

Preferably, the member units are frame corner members and frame edge members; the frame corner members are distributed on the four corners of the backplane, and the frame edge members are distributed on the four edges of the backplane.

Preferably, the number of the support members arranged between adjacent member units is multiple. Both the number and length of the support members can be purposefully set in accordance with the distance between two adjacent member units. When the the distance between two adjacent member units is long, a plurality of support members can be arranged.

The invention further provides a backlight module, comprising a middle frame, and a backplane; the middle frame is provided with a support surface used for supporting the LCD panel; the middle frame comprises a plurality of member units, and a distance is reserved between two adjacent member units. The backlight module further comprises a support member(s) used for assistantly supporting the LCD panel. The support member is provided with a hook, and the support member is hung on one side wall of the backplane by the hook. The support member is positioned between two adjacent member units, and the support surface of the support member is flush with the support surface of the middle frame.

Preferably, the support member is formed by bending a plate. The width of the hook of the support member is equal to the length of the support member.

Preferably, the width of the support surface of the support member is less than or equal to that of the support surface of the middle frame.

Preferably, the side wall of the backplane is further provided with a positioning structure used for preventing the support member from sliding on the side wall.

Preferably, the positioning structure comprises a through hole arranged in the support member, and a lug boss arranged on the upper end surface of the side wall of the backplane; the through hole is sheathed on the lug boss.

Preferably, the positioning structure comprises a notch arranged in the side wall of the backplane; the width of the notch is longer than or equal to the length of the support member.

Preferably, the member units are frame corner members, and are distributed on the four corners of the backplane; or the member units are frame edge members, and are distributed on the four edges of the backplane.

Preferably, the member units are frame corner members and frame edge members; the frame corner members are distributed on the four corners of the backplane, and the frame edge members are distributed on the four edges of the backplane.

Preferably, the number of the support members arranged between adjacent member units is multiple.

In the invention, the direction of the support member parallel with the side wall of the backplane is the length direction, and the direction of the support member perpendicular to the side wall of the backplane is the width direction.

Advantages of the invention are summarized below: the support members of the LCD panel are additionally arranged on the LCD device of the invention; the support member(s) is arranged between two member units when the distance between two adjacent member units is long; and the support surface of the support member is flush with the support surface of the middle frame to provide intermediate support force, so as to enable the support force obtained by the LCD panel is more uniform, and prevent excessive local stress. By being provided with the hook, the support member can be conveniently hung on the side wall of the backplane, thereby saving time and effort during assembly.

### BRIEF DESCRIPTION OF FIGURES

FIG. 1 is a structure diagram of a first example of an LCD device of the invention;

FIG. 2 is an enlarged view of A shown in FIG. 1;

FIG. 3 is a structure diagram of a second example of an LCD device of the invention; and

FIG. 4 is an enlarged view of B shown in FIG. 3;

Legends: 1. middle frame; 11. frame corner member; 12. frame edge member; 13. support surface; 2. backplane; 21. side wall; 22. lug boss; 23. notch; 3. LCD panel; 4. support member; 41. hook; 42. support surface; 43. through hole.

### DETAILED DESCRIPTION

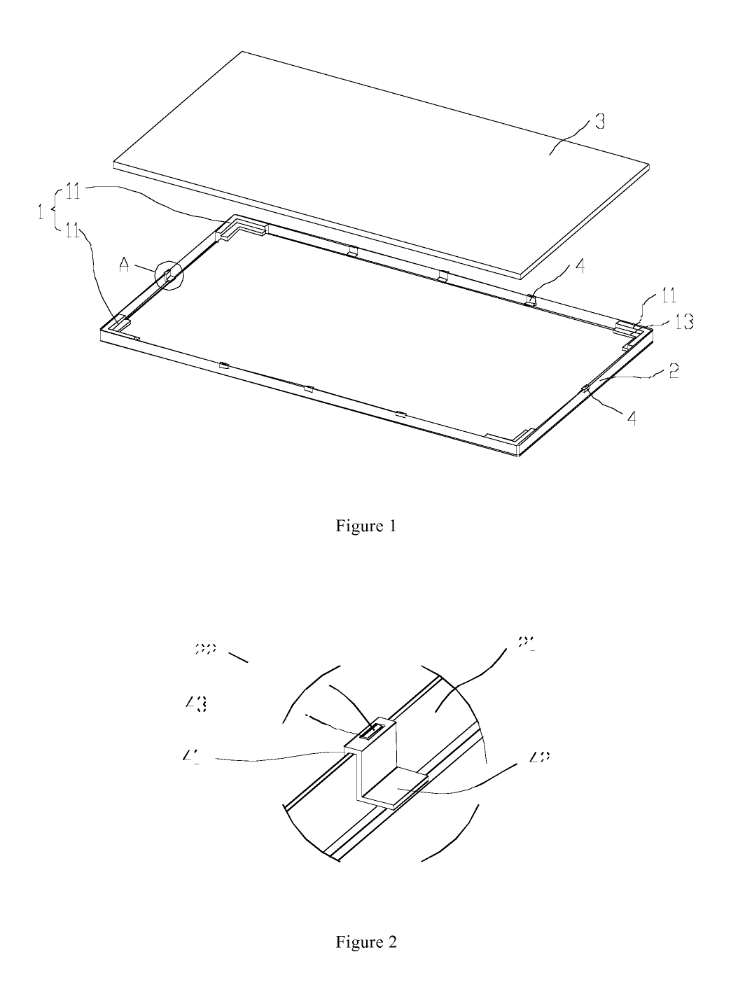

The invention provides an LCD device, comprising a backlight module; the backlight module comprises a middle frame 1, and a backplane 2. FIG. 1 and FIG. 2 show a first example of the LCD device. The LCD device comprises a middle frame 1, a backplane 2, and an LCD panel 3; the LCD panel 3 is arranged on a support surface 13 of the middle frame 1; the middle frame 1 comprises a plurality of member units, and a distance is reserved between two adjacent member units. The backlight module of the LCD device further comprises a support member(s) 4 for assistantly supporting LCD panel 3; the support member 4 is provided with a hook 41, and the support member 4 is hung on the side wall 21 of the backplane 2 by the hook 41. The support member(s) 4 is positioned two adjacent member units, and the support surface 42 of the support member 4 is flush with the support surface 13 of the middle frame 1. In the example, preferably, the support surface 42 is a plane. The plane can better provide support for the LCD panel 3, to avoid the adverse effect of point contact and line contact on the LCD panel 3.

The support members 4 of the LCD panel 1 are additionally arranged on the LCD device of the invention, the support member(s) is arranged between two member units when the distance between two adjacent member units is long, and support surface 42 of the support member 4 is flush with the support surface 13 of the middle frame to provide intermediate support force, so as to enable the support force obtained by the LCD panel 3 is more uniform, and prevent excessive local stress. By being provided with the hook 41, the support member 4 is conveniently hung on the side wall 21 of the backplane, thereby saving time and effort during assembly.

In the example, the member units are four frame corner members 11, and are distributed on the four corners of the backplane 2. A distance is reserved between every two frame corner members 11. The distance in the length direction of the middle frame is more than that in the width direction. In the example, the frame corner members 11 can be fixed on the backplane 2 by screws, fasteners, etc. The four side walls 21 of the backplane 2 are respectively provided with one or more support members 4. The length or the total length of the support members 4 arranged between adjacent member units is less than the distance between adjacent member units; thus, the support members 4 are successfully hung on the side walls 21 of the backplane. The width of the support surface of each support member 4 is less than or equal to that of the support surface of the middle frame, to avoid blocking out the light emitted by the backlight module. In the example, each the side wall 21 of the backplane 2 in the length direction is respectively provided with three support members 4, and each the side wall 21 of the backplane 2 in the width direction is respectively provided with one support member 4.

In the example, the support member is formed by bending a plate. The width of the hook 41 of the support member is equal to the length of the support member 4, thereby avoiding the inclination of the support member 4, to enable the support surface of the support member to be fully attached to the surface of the LCD panel.

In the example, each side wall 21 of the backplane is further provided with a positioning structure used for preventing the support member 4 from sliding on the side wall.

The positioning structure comprises a through hole 43 arranged in the support member 4, and a lug boss 22 arranged on the upper end surface of the side wall of the backplane; the through hole 43 is sheathed on the lug boss 22. The positioning structure enables the support member 4 to have a fixed position, and then enables the LCD panel 3 to obtain reasonable support force in an appropriate position and not to be affected by the factors such as position error when being manually placed.

Optionally, the side wall of the backplane of the invention may be not provided with a positioning structure used for preventing the support member from sliding on the side wall. For example, interference fit exists between the hook of the support member and the side wall of the backplane, and then the support member is prevented from sliding by the friction between the hook and the side wall of he backplane.

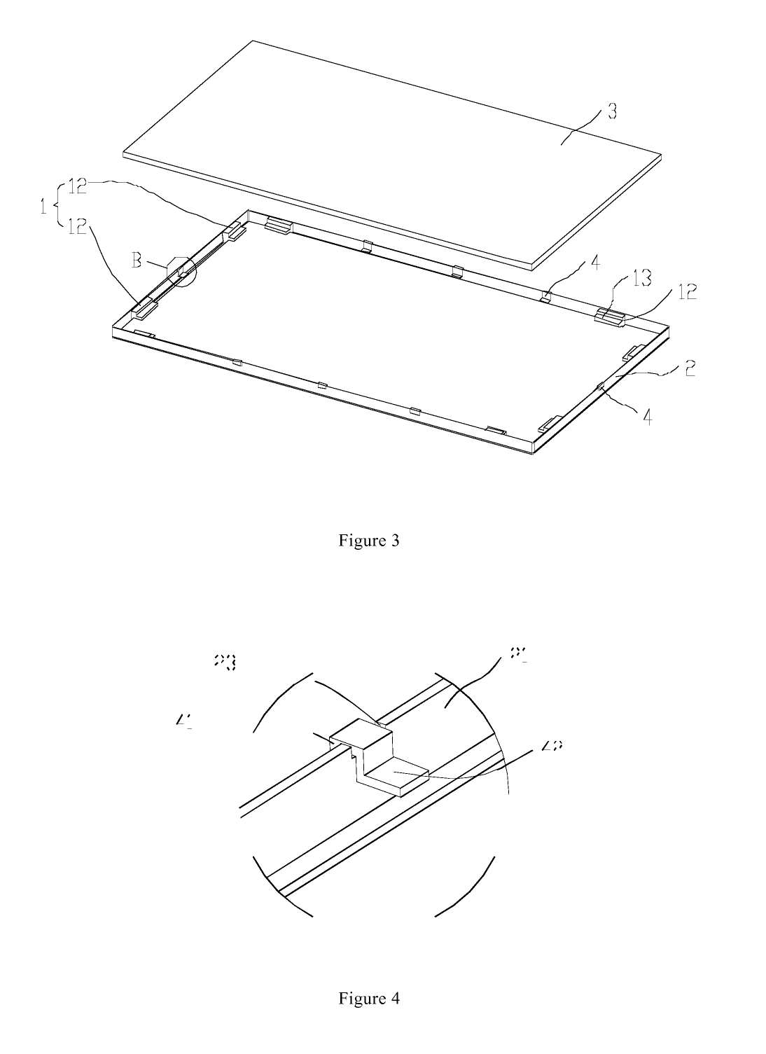

FIG. 3 and FIG. 4 show a second example of the LCD device of the invention, and the second example is different from the first example in that: the member units are frame edge members 12, and are distributed on the four edges of the backplane 2. Each side wall 21 of the backplane is further provided with a positioning structure used for preventing the support member 4 from sliding on the side wall 21. The positioning structure comprises a notch 23 arranged in the side wall 21 of the backplane, and the width of the notch 23 is greater than or equal to the length of the support member 4. The support member 4 is limited in the notch 23. The function of the positioning structure in the second example is consonant with that of the positioning structure in the first example.

In the example, the frame edge members can be fixed on the backplane by screws, fasteners, etc. Alternatively, fixing columns can be arranged on the frame edge members, and fixing holes can be arranged in the side walls of the backplane. The fixing columns of the frame edge members are inserted in the fixing holes of the backplane; thus, the frame edge members are fixed on the backplane.

In the example, the support members can be arranged on the four corners of the backplane, to support the four corners of the LCD panel.

In the invention, both the number and length of the support member can be purposefully set in accordance with the distance between two adjacent member units. However, the size of the support members is preferably unified into one specification, to facilitate management. When the the distance between two adjacent member units is long, a plurality of support members are arranged; when the distance between two adjacent member units is short, only one support member is arranged, or no support member is arranged.

In the invention, the member units can be frame corner members and frame edge members; the frame corner members are distributed on the four corners of the backplane, and the frame edge members are distributed on the four edges of the backplane. When the distance between two frame edge members or the distance between the frame edge member and the frame corner member is long, support member(s) are appropriately arranged, to provide assistant support force for the LCD panel.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

We claim:

1. An LCD device, comprising a middle frame, a backplane, and an LCD panel; wherein said LCD panel is arranged on a support surface of said middle frame; said middle frame comprises a plurality of member units, and a distance is reserved between two adjacent member units; said LCD device further comprises support members used for assistantly supporting said LCD panel; each said support member is provided with a hook, and said support member is hung on one side wall of said backplane by said hook; said support member(s) is positioned between two adjacent member units, and a support surface of said support member is flush with a support surface of said middle frame; said support member is formed by bending a plate; the width of the hook of said support member is equal to the length of said support member, and the width of the support surface of said support member is less than or equal to that of the support surface of said middle frame; the side wall of said backplane is further provided with a positioning structure used for preventing said support member from sliding on the side wall; said positioning structure comprises a through hole arranged in said support member, and a lug boss arranged on the upper end surface of the side wall of said backplane; said through hole is sheathed on said lug boss; said member units are frame corner members, and are distributed on the four corners of said backplane; or said member units are frame edge members, and are distributed on the four edges of said backplane; the number of said support member(s) arranged between part of adjacent member units is multiple.

2. An LCD device, comprising: a middle frame, a backplane, and an LCD panel;
wherein said LCD panel is arranged on a support surface of said middle frame; said middle frame comprises a plurality of member units, and a distance is reserved between two adjacent member units; said LCD device further comprises a support member(s) for assistantly supporting said LCD panel; said support member is provided with a hook, and said support member is hung on one side wall of said backplane by said hook; said support member(s) is positioned between two adjacent member units, and the support surface of said support member is flush with the support surface of said middle frame.

3. The LCD device of claim 2, wherein said support member is formed by bending a plate; the width of the hook of said support member is equal to the length of said support member.

4. The LCD device of claim 2, wherein the width of the support surface of said support member is less than or equal to that of the support surface of said middle frame.

5. The LCD device of claim 2, wherein each side wall of said backplane is further provided with a positioning structure used for preventing said support member from sliding on said side wall.

6. The LCD device of claim 5, wherein said positioning structure comprises a through hole arranged in said support member, and a lug boss arranged on the upper end surface of the side wall of said backplane; said through hole is sheathed on said lug boss.

7. The LCD device of claim 5, wherein said positioning structure comprises a notch arranged in the side wall of said backplane; the width of said notch is longer than or equal to the length of said support member, and said support member is limited in said notch.

8. The LCD device of claim 2, wherein said member units are frame corner members, and are distributed on the four corners of said backplane; or said member units are frame edge members, and are distributed on the four edges of said backplane.

9. The LCD device of claim 2, wherein said member units are frame corner members and frame edge members; said frame corner members are distributed on the four corners of said backplanethe, and said frame edge members are distributed on the four edges of said backplane.

10. The LCD device of claim 2, wherein the number of said support member(s) arranged between part of adjacent member units is multiple.

11. A backlight module, comprising: a middle frame, and a backplane; wherein said middle frame is provided with a support surface used for supporting said LCD panel; said middle frame comprises a plurality of member units, and a distance is reserved between two adjacent member units; wherein said backlight module further comprises a support member(s) used for assistantly supporting said LCD panel; said support member is provided with a hook, and said support member is hung on one side wall of said backplane by said hook; said support member is positioned between two adjacent member units, and the support surface of said support member is flush with the support surface of said middle frame.

12. The backlight module of claim 11, wherein said support member is formed by bending a plate; the width of the hook of said support member is equal to the length of said support member.

13. The backlight module of claim 11, wherein the width of the support surface of said support member is less than or equal to that of the support surface of said middle frame.

14. The backlight module of claim 11, wherein each side wall of said backplane is further provided with a positioning structure used for preventing said support member from sliding on said side wall.

15. The backlight module of claim 14, wherein said positioning structure comprises a through hole arranged in said support member, and a lug boss arranged on the upper end surface of the side wall of said backplane; said through hole is sheathed on said lug boss.

16. The backlight module of claim 14, wherein said positioning structure comprises a notch arranged in the side wall of said backplane; the width of said notch is longer than or equal to the length of said support member, and said support member is limited in said notch.

17. The backlight module of claim 11, wherein said member units are frame corner members, and are distributed on the four corners of said backplane; or said member units are frame edge members, and are distributed on the four edges of said backplane.

18. The backlight module of claim 11, wherein said member units are frame corner members and frame edge members; said frame corner members are distributed at the four corners of said backplanethe, and said frame edge members are distributed on the four edges of said backplane.

19. The backlight module of claim 11, wherein the number of said support member(s) arranged between part of adjacent member units is multiple.
